(19) United States
(12) Patent Application Publication
(10) Pub. No.: US 2025/0098277 A1
(43) Pub. Date: Mar. 20, 2025

(54) SYSTEMS AND METHODS FOR MANUFACTURING SEMICONDUCTOR DEVICES

(71) Applicant: Tokyo Electron Limited, Tokyo (JP)

(72) Inventor: Eric Chih-Fang LIU, Albany, NY (US)

(73) Assignee: Tokyo Electron Limited, Tokyo (JP)

(21) Appl. No.: 18/370,835

(22) Filed: Sep. 20, 2023

(51) Int. Cl. H01L 21/8238; H01L 27/092; H01L 29/423; H01L 29/66; H01L 29/786

(52) U.S. Cl. CPC H10D 84/038; H10D 30/014; H10D 30/6735; H10D 30/6757; H10D 84/0184; H10D 84/0188; H10D 84/0195; H10D 84/856

(57) ABSTRACT

A method for fabricating semiconductor devices includes forming an opening. The method includes forming a blanket layer along vertical sidewalls of the opening. The method includes etching through the first recess through a first source/drain structure of the first semiconductor channel. The method includes filling the first recess with a dielectric material. The method includes removing the blanket layer between the dielectric material and the sidewall, to define a second and third recess opposite the dielectric material. The method includes etching the surface of the semiconductor device to define a fourth recess above a second source/drain structure of the first semiconductor channel. The method includes extending the third and fourth recesses through the first and second source/drain structures of the first semiconductor channel, to a first and second source/drain structure of the second semiconductor channel.

### TECHNICAL FIELD

This disclosure relates to semiconductor devices. The semiconductor devices can include stacked transistors, such as complementary field effect transistors (CFETs).

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors or channels thereof are stacked on top of each other. 3D integration, i.e., the vertical stacking of multiple devices, aims to overcome scaling limitations experienced in planar devices by increasing transistor density in volume rather than area. Although device stacking has been successfully demonstrated and implemented, various embodiments can include numerous operations, and may include minimum feature distances which limit device density and performance.

### SUMMARY

The present disclosure relates to forming conductive elements for 3D semiconductor circuits. For example, the 3D semiconductor circuits can include stacked transistors for complementary field effect transistor (CFET) pairs, such as a p-type field-effect transistor (FET) and an n-type FET forming and inverter.

By forming various components of the CFET employing self-aligned contacts, sequential operations can form a semiconductor device having dimensions which are less than a lithographic dimension of a process employed to form the semiconductor device. For example, recesses for contacts such as a VDD and VSS contacts can be formed from a larger recess, based on an ALD process applied to the sidewalls of the larger contact. That is, a lateral dimension of the VDD and VSS contacts can be controlled, which may reduce ohmic losses or capacitance, or increase device density. Moreover, by selection of selectively etchable materials, a mask can be formed over the semiconductor device which includes lateral margin such that a misaligned mask or other deviation in process may not impact a function of a device (because the other portions of the device may be etched at a lesser rate than a target material).

Moreover, employing punch-through operations to vertically align connections between stacked transistors and their abutting features can maintain a control of electron transport, and other device functionality. That is, forming interconnections between an upper and lower transistor of a CFET pair according to the present disclosure can maintain a balance of operation between the CFET pair in a dense device which may exceed a density realized with other techniques, such as techniques which are limited by a lithographic limit, such as a reticle or other resolution limit for a minimum feature dimension.

One aspect of the present disclosure is directed to a method for fabricating semiconductor devices. The method includes providing a semiconductor device including a first semiconductor channel and a second semiconductor channel, vertically spaced from the first semiconductor channel. The method includes etching a surface of the semiconductor device to define a first recess bounded by a first sidewall and a second sidewall, opposite the first sidewall. The method includes forming a blanket layer over the first sidewall and the second sidewall. The method includes etching, directionally, a lower surface of the first recess through a first source/drain structure of the first semiconductor channel. The method includes filling the first recess with a first dielectric material. The method includes removing the blanket layer between the first dielectric material and the second sidewall, to define a second recess. The method includes removing the blanket layer between the first dielectric material and the first sidewall to define a third recess. The method includes etching the surface of the semiconductor device to define a fourth recess vertically spaced from a second source/drain structure of the first semiconductor channel. The method includes extending, directionally, each of the third recess and the fourth recess, through the respective first and second source/drain structures of the first semiconductor channel, to a respective first and second source/drain structures of the second semiconductor channel.

Another aspect of the present disclosure is directed to a method for fabricating semiconductor devices. The method includes providing a semiconductor device having a first semiconductor channel for a first transistor and a second semiconductor channel for a second transistor, vertically spaced from the first semiconductor channel. The method includes etching a surface of the semiconductor device to define an opening bounded by a first sidewall and a second sidewall, opposite the first sidewall. The method includes forming a blanket layer over the first sidewall and the second sidewall. The method includes etching, directionally, a lower surface of the opening through a first source/drain structure of the first transistor. The method includes filling the first recess with a first dielectric material. The method includes removing a portion of the blanket layer between the first dielectric material and the second sidewall, to define a second recess. The method includes removing a portion of the blanket layer between the first dielectric material and the first sidewall to define a third recess. The method includes etching the surface of the semiconductor device to define a fourth recess over a second source/drain structure of the first transistor. The method includes extending, directionally, each of the third recess and the fourth recess, through the respective first and second source/drain structures of the first transistor, to a respective third and fourth source/drain structures of the second transistor.

Another aspect of the present disclosure is directed to a method for fabricating semiconductor devices. The method includes forming a blanket layer along opposite sidewalls to define a recess laterally centered between the opposite sidewalls. The method includes forming an isolation layer extending through the recess and a first source/drain region vertically inferior to the recess. The method includes forming a first self-aligned contact opening laterally defined between the isolation layer and an input for an inverter. The method includes forming, simultaneously, a second self-aligned contact opening and a third self-aligned contact opening for a first supply voltage for the inverter and an output for the inverter. The method includes filling the first self-aligned contact opening with a conductive element to connect to a first source/drain region of a first transistor of the inverter. The method includes filling the second self-aligned contact opening with a second conductive element to connect to a first source/drain region of a second transistor of the inverter. The method includes filling the third self-aligned contact opening with a third conductive element to connect to a second source/drain region of each of the first transistor and the second transistor.

The method may include simultaneously forming the third recess and the fourth recess.

The first semiconductor channel can include a plurality of nanostructures vertically spaced from each other.

One of the first semiconductor channel or the second semiconductor channel can be a channel of an n-type transistor and the other of the first semiconductor channel or the second semiconductor channel can be a channel of a p-type transistor.

The method may further include forming a conductive layer in the second, third, and fourth recess and over the semiconductor device. The method may further include planarizing the surface of the conductive layer to electrically decouple the conductive layer between a first conductive element disposed in the second recess, a second conductive element disposed in the third recess, and a third conductive element disposed in the fourth recess.

Extending the fourth recess can include etching a spacer layer. The spacing layer can be disposed between the second source/drain structure of the first semiconductor channel, and the fourth source/drain structure of the second semiconductor channel.

A lateral dimension of the second recess may be equal to a lateral dimension of the third recess.

Forming the second recess can include forming a patternable layer along the surface of the semiconductor device. The patternable layer can include a minimum feature dimension which is greater than a lateral dimension of any of the second recess, the third recess, or the fourth recess.

The method can include extending the third recess and the fourth recess prior to a formation of the second recess.

The method can include extending the third recess and the fourth recess prior to a formation of the second recess.

The method can include forming the blanket layer by performing multiple cycles of an atomic layer deposition (ALD) process.

The method can include forming a gate disposed laterally between the second recess and the fourth recess. The gate can electrically connect to a gate oxide of the first semiconductor channel and the second semiconductor channel.

The gate can surround the first semiconductor channel and the second semiconductor channel to form a gate-all-around (GAA) complementary field-effect transistor (FET).

Another aspect of the present disclosure is directed to a method for fabricating semiconductor devices. The method includes providing a first transistor comprising a first semiconductor channel having a first end connected to a first source/drain and a second end connected to a second source drain. The method includes providing a second transistor comprising a first semiconductor channel having a third end connected to a third source/drain and a fourth end connected to a fourth source/drain. The second semiconductor channel is vertically spaced from and laterally aligned with the first semiconductor channel. The first source/drain is vertically spaced from and laterally aligned with the third source/drain. The second source/drain is vertically spaced from and laterally aligned with the fourth semiconductor channel. The method includes exposing the first source/drain by etching through a first portion of the third source/drain. The method includes filling the etched first portion with a dielectric material to form an isolation layer. The method includes forming a first conductive element to contact the first source/drain, a second conductive element to contact the third source/drain, and a third conductive element to contact the second and fourth source/drains, the isolation layer interposed between the first conductive element and the second conductive element.

The method can include each of filling the first, second, and third self-aligned contact opening simultaneously.

In some instances, the first transistor can be an n-type transistor and the second transistor can be a p-type transistor.

In some instances, the first transistor can be a p-type transistor and the second transistor can be an n-type transistor.

Another aspect of the present disclosure is directed to a semiconductor device. The semiconductor device includes a first source/drain region of a first semiconductor channel laterally spaced from a second source/drain region of the first semiconductor channel. The semiconductor device includes a first source/drain region of a second semiconductor channel laterally spaced from a second source/drain region of the first semiconductor channel, the first semiconductor channel vertically spaced from the second semiconductor channel. The semiconductor device includes a first conductive element extending to the first source/drain region of the first semiconductor channel. The semiconductor device includes a second conductive element extending to the first source/drain region of the second semiconductor channel. The second conductive element extends a same lateral dimension as the first conductive element along an axis extending from the first conductive element to the second conductive element. A third conductive element extends a same vertical dimension as the second conductive element. The third conductive element extends through and electrically connects to the second source/drain region of the first semiconductor channel. The third conductive element extends to and electrically connects to the second source/drain region of the second semiconductor channel.

Another aspect of the present disclosure is directed to a semiconductor device. The semiconductor device includes a first source/drain region of a first transistor laterally spaced from a second source/drain region of the first transistor, the first transistor vertically spaced from a second transistor. The semiconductor device includes a third source/drain region of a second transistor, the third source/drain region laterally spaced from a fourth source/drain region. The semiconductor device includes a first conductive element extending in a vertical direction to contact the first source/drain region and a second conductive element extending in the vertical direction to contact the third source/drain region, the second conductive element extending a same lateral dimension as the first conductive element along an axis extending from the first conductive element to the second conductive element. The semiconductor device includes a third conductive element extending in the vertical direction to contact the second source/drain region and the fourth source drain region. The first conductive element extends, vertically, a lesser distance than either of the second conductive element or the third conductive element.

The first transistor of the semiconductor device can be an n-type transistor; the second transistor of the semiconductor device can be a p-type transistor.

The first conductive element, the second conductive element, and the third conductive element can be interconnected to form an inverter.

The first semiconductor channel can include multiple nanostructures vertically spaced from each other.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Indeed, various features of the figures may be intentionally emphasized to depict various features thereof. Unless indicated as representing the background art, the figures represent aspects of the disclosure. For purposes of clarity, not every component may be labeled in every drawing. In the drawings:

FIG. 1 illustrates a method for forming a semiconductor device, in accordance with some embodiments.

FIG. 2 is a cross-sectional view of a stacked nanosheet structure, in accordance with some embodiments.

FIG. 3 is a cross-sectional view of a monolithic semiconductor device formed from a stacked nanosheet structure, in accordance with some embodiments.

FIG. 4 is an isometric view of the semiconductor device of FIG. 3, in accordance with some embodiments.

FIGS. 5, 6, 7, 8, 9, 10, 11, 12, 13, 14, 15, and 16 illustrate respective cross-sectional views of a semiconductor device during various fabrication stages of the method of FIG. 1, in accordance with some embodiments.

FIG. 17 is an isometric view of a semiconductor device which may be formed according to the various fabrication stages of the method of FIG. 1, in accordance with some embodiments.

FIG. 18 is a cross-sectional view of a replacement of a dummy gate with a metal gate structure, in accordance with some embodiments.

FIG. 19 is a hybrid view of a semiconductor device and circuit, in accordance with some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Likewise, although the Figures and aspects of the disclosure may show or describe devices herein as having a particular shape, it should be understood that such shapes are merely illustrative and should not be considered limiting to the scope of the techniques described herein. For example, although certain figures show various layers defining contacts or gates in a trench configuration, other shapes are also contemplated, and indeed the techniques described herein may be implemented in any shape or geometry.

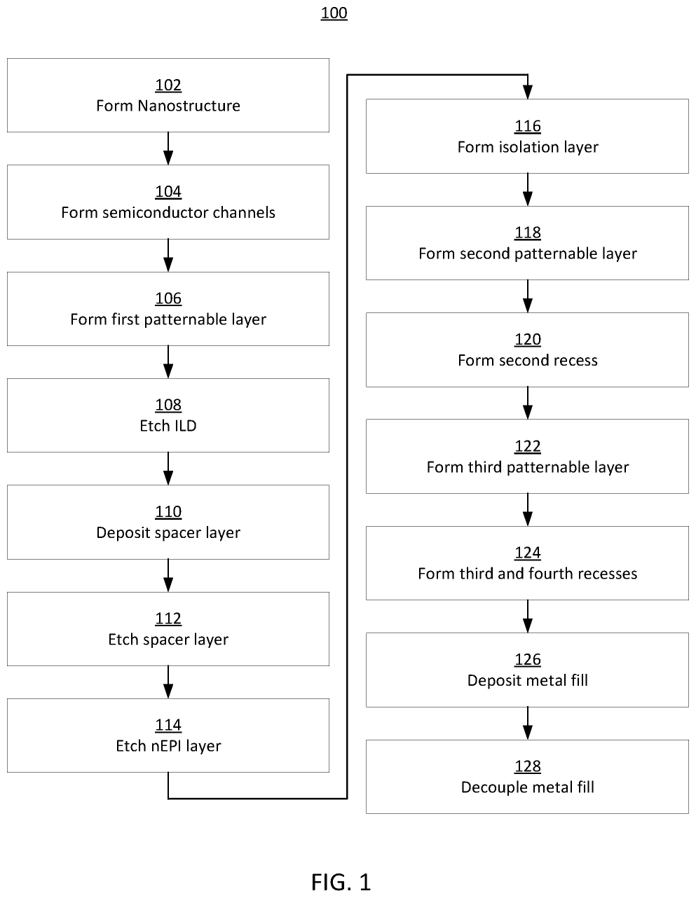

FIG. 1 illustrates a flowchart of an example method 100 for forming a semiconductor device. For example, the semiconductor device can include a plurality of memory or logic cells such as a DRAM memory, an SRAM memory (e.g., an inverter thereof), an inverter of a logic circuit, or the like. Various memory openings can be formed to connect conductive elements (e.g., metal gates or source/drain connections). For example, the conducive elements can interconnect various layers of the semiconductor device. The method 100 can be performed in conjunction with two or more semiconductor channels, vertically spaced from each other. Such channels can form a stacked CFET including a P-type transistor having one or more channels, and an N-type transistor having one or more channels.

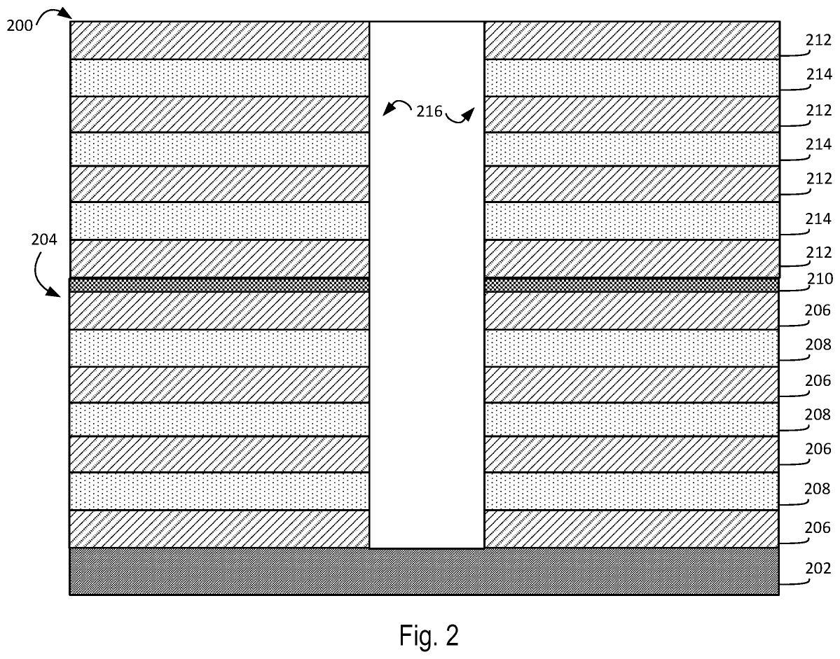

In various embodiments, operations of the method 100 may be associated with cross-sectional views of an example semiconductor device at various fabrication stages as shown in FIGS. 2 to 16, which will be discussed in further detail below. It should be understood that the semiconductor device 200, shown in FIGS. 2 to 16, may include a number of other devices such as inductors, fuses, capacitors, coils, etc., while remaining within the scope of the present disclosure. For example, a semiconductor device can include further layers of stacked transistors or channel portions thereof and interconnections therebetween.

In brief overview, the method 100 starts with operation 102 of forming a stack over a substrate 202. The method 100 continues to operation 104 of forming a first and second semiconductor channel from the stack. The method 100 continues to operation 106 of forming a patternable layer over the semiconductor device. The method 100 continues to operation 108 of etching an interlayer dielectric layer to form a recess. The method 100 continues to operation 110 of depositing a spacer layer to form a spacer along the sidewall of the recess of operation 108. The method 100 continues to operation 112 of etching a spacer layer formed over an n-type FET. The method 100 continues to operation 114 of etching an epitaxial layer of the n-type FET. The method 100 continues to operation 116 of filling the recess with an isolation layer. The method 100 continues to operation 118 of forming a patternable layer over a contact location for the n-type FET. The method 100 continues to operation 120 of forming a second recess over the contact location for the n-type FET. The method 100 continues to operation 122 of forming a patternable layer over the semiconductor device for third and fourth recesses. The method 100 continues to operation 124 of forming the third recess and fourth recess. The method 100 continues to operation 126 of depositing a metal fill in the second recess, third recess, and fourth recess. The method 100 continues to operation 128 of recessing the top surface of the metal fill to electrically decouple the metal fill between the second recess, the third recess, and the fourth recess.

According to various embodiments, various operations of the method may be omitted, added, modified, or combined. For example, one or more of the recesses, etches, or patternable layers may be formed simultaneously. In another example, when performed according to various sequences, the operations of the method can include additional or fewer operations. For example, changes the sequence of various etching operations can correspond to additional or fewer patternable layers formed over the semiconductor device, a formation of a hardmask may obviate one or more of the patternable layers, or another removal process may be employed.

Corresponding to operation 102 of FIG. 1, FIG. 2 is a cross-sectional view of the semiconductor device 200 in which, nanostructures 216 are formed over a substrate 202, in accordance with various embodiments. For example, the nanostructures 216 can be formed from a plurality of nanosheets to form heterostructures, including, for example, a spacer layer and a p-type silicon layer for a p-type transistor and a spacer layer and an n-type silicon layer for a n-type transistor.

The substrate 202 includes a semiconductor material substrate 202, for example, silicon. Alternatively, the substrate 202 may include other elementary semiconductor material such as, for example, germanium. The substrate 202 may also include a compound semiconductor such as silicon carbide, gallium arsenic, indium arsenide, and indium phosphide. The substrate 202 may include an alloy semiconductor such as silicon germanium, silicon germanium carbide, gallium arsenic phosphide, and gallium indium phosphide. In one embodiment, the substrate 202 includes an epitaxial layer. For example, the substrate 202 may have an epitaxial layer overlying a bulk semiconductor. Furthermore, the substrate 202 may include a semiconductor-on-insulator (SOI) structure. For example, the substrate 202 may include a buried oxide (BOX) layer formed by a process such as separation by implanted oxygen (SIMOX) or other suitable technique, such as wafer bonding and grinding.

As shown, a stack 204 is formed over the substrate 202. The stack 204 can include one or more sublayers to form a logic or memory device therefrom according to the present disclosure. For example, the stack 204 can be a stack of alternating oxide-nitride-oxide layers to form a memory device or alternating semiconductive and sacrificial layers (e.g., silicon and silicon germanium). The first sub-layer 206 of the stack 204 may be a semiconductor layer such as silicon. The first sub-layer 206 can be formed according to a deposition process, growth process, or the like. For example, the first sub-layer 206 may be formed by a physical vapor deposition (PVD), high density plasma chemical vapor deposition (HDP-CVD), a flowable CVD (FCVD) epitaxial process, the like, or combinations thereof. Other materials and/or other formation processes may be used in various embodiments. Subsequent to the formation of the first sub-layer 206, a second sub-layer 208 is formed there over. For example, the second sub-layer 208 can be formed by a same or different process as the first sub-layer 206. One or more of the semiconductive layers can be lightly doped to form a conduction channel. For example, a channel material (e.g., silicon) for a p-type transistor can be lightly doped with an n-type dopant (e.g., phosphorus, arsenic, or antimony), or a channel material for an n-type transistor can be lightly doped with a p-type dopant (e.g., boron, gallium, or indium). In some embodiments, the channels may be or comprise an intrinsic semiconductor, or a semiconductor which is not intentionally doped.

With continued reference to operation 102, the stack 204 can continue to build up by alternating the first sub-layer 206, and the second sub-layer 208. For example, each layer can have a thickness of (substantially) less than 1 μm. The number of layers of the stack 204 can be proportional to a number of conduction channels of a transistor, thus increasing a number of layers may be desirable in some embodiments. That is, the layers of the stack 204 can correspond to vertically spaced nanostructures of a transistor; wherein the nanostructures corresponding to a transistor can be referred to, collectively, as a conductive channel. A hardmask or other spacer layer 210 can intermediate portions of the stack 204 such as between a first portion of layers for a p-type transistor, and a second portion of layers for an n-type transistor. For example, as depicted, alternating third sub-layers 212 and fourth sub-layers 214 can be formed over the spacer layer 210 to define a first and second portion of the semiconductor device 200 corresponding to first and second transistors. The stack 204 can thereafter be etched to form separate nanostructures 216 therefrom, such as to form source/drain regions (not depicted) along the terminal portions of the conductive channels.

The sub-layers described herein are not intended to be limiting, and various further sub-layers (e.g., additional spacers or dummy gates) can be formed over or intermediating the depicted layers. Moreover, some layers may be formed over other features such that the layers may not be substantially flat nanosheets. For example, the spacer layer 210 can be formed over other features of the semiconductor device 200 to define a three dimensional structure, as depicted hereinafter.

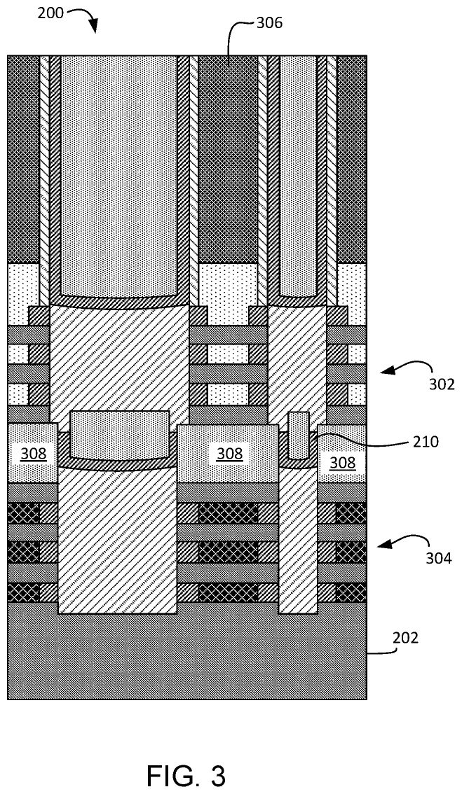

Corresponding to operation 104 of FIG. 1, FIG. 3 is a cross-sectional view of the semiconductor device 200 in which semiconductor channels are formed from the nanostructures, in accordance with various embodiments.

The semiconductor channels can be formed from the nanostructures 216 of FIG. 2. For example, the nanosheets of FIG. 2 can be horizontally etched and various oxides (e.g., silicon dioxide) can be formed thereover to define various transistors features (e.g., a junction oxide) such that the conduction channels are electrically to the source/drain regions so as to cause the channel to be actuated by the gate. For example, the semiconductor channel structures disposed below the spacer layer 210 can correspond to a first transistor 302 (e.g., a p-type transistor or an n-type transistor). The semiconductor channel structures disposed above the spacer layer 210 can correspond to a second transistor 304 (e.g., a p-type or n-type field-effect-transistor (FET)). Where the first transistor 302 and the second transistor 304 are of a different type, the interconnections formed therebetween can form a CFET for use in, for example, an inverter. The first transistor 302 and second transistor 304 can be intermediated by middle dielectric isolation (MDI). The first transistor 302 and second transistor 304 can be vertically spaced by a dielectric portion 308. In various further embodiments, the two transistors may be of a same type, for another circuit or circuit portion (e.g., may be configured as a Darlington pair, parallel drivers, or so forth).

A dummy or metal gate structure 306 can be formed over an upper surface of the first transistor 302. Another layer can be formed (e.g., epitaxially grown, deposited, etc.) over lateral ends of the semiconductor channels corresponding to the first transistor 302 and second transistor 304, to form corresponding source/drain regions which may also be referred to as epitaxial (EPI) regions (e.g., a pEPI, corresponding to a p-type transistor or a nEPI corresponding to an n-type transistor). Other portions of the semiconductor device 200 can include various spacer layers, inter-layer dielectrics (ILD), and the like. Some such features will be apparent hereinafter where they may be referred to be their relative selectivity, functions, constituent materials, and so forth. For example, various operations may be employed to form the semiconductor device 200 of FIG. 3. The depicted embodiment is not intended to be limiting; for example, the first transistor 302 or second transistor 304 can include additional or fewer semiconductor channels, or can be various types (e.g., FinFET, GAAFET, n-type, p-type, and so forth).

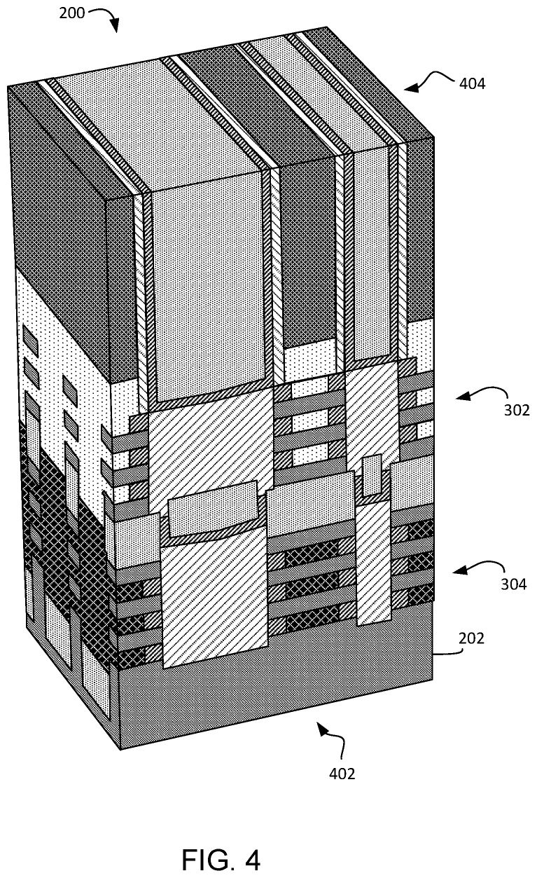

With continued correspondence to operation 104 of FIG. 1, FIG. 4 is a perspective view of the semiconductor device 200 of FIG. 3. Depicted is a same front face 402 of the device (e.g., shown as a cut plane of the semiconductor device 200 of FIG. 3). The semiconductor device 200 can include the depicted features in a repeating pattern extending along the front face 402 or perpendicular thereto along an axis of a same lateral plane. For example, the upper face 404 of the semiconductor device 200 can include a repeating pattern of features intermediating by a spacer or other insulative barrier (not depicted).

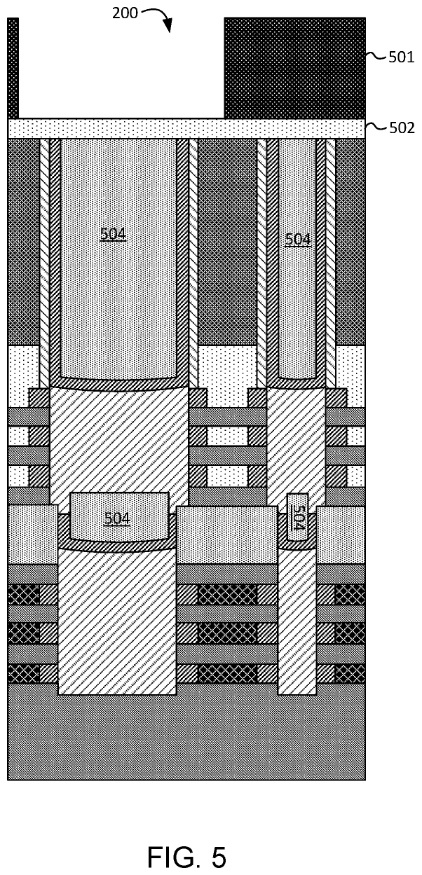

Corresponding to operation 106 of FIG. 1, FIG. 5 is a cross-sectional view of the semiconductor device 200 in which a first patternable layer 502 is formed over the semiconductor device 200, in accordance with various embodiments.

A first patternable layer 502, such as a positive or negative photoresist mask 501 with patterns can be formed over the semiconductor device 200. The pattern may include a periodic pattern such that periodic openings are formed across the semiconductor device 200. The first patternable layer 502 may comprise the photoresist, or another material (e.g., hardmask or other mask material) formed into openings of the first patternable layer 502 to form a patterned layer. The upper surface of the semiconductor device 200 and the first patternable layer 502 may have different etching selectivity's. For example, the first patternable layer 502 may be more resistive to an etchant than the material of the semiconductor device 200. The patterned layer may remain substantially intact during subsequent operations of the method 100.

The first patternable layer 502 can include one or more sub-layers or sequential applications thereof. For example, in some embodiments, the first patternable layer 502 can be employed to form an opening in a photoresist mask 501, and another patternable layer to further define an opening, further described hereinafter, with regard to operation 108. In some embodiments, the first patternable layer 502 is formed over other interlayer dielectric (ILD) 504 portions, and an etchant employed, hereinafter, at operation 108, is selective to the ILD 504 portions relative to other portions of the semiconductor device 200. For example, a dimension of the first patternable layer 502 can be laterally medial (or approximately so) to the ILD 504 portion to be removed and other ILD 504 portions. That is, the position of the first patternable layer 502 can vary laterally without changing an etch resulting therefrom so long as the first patternable layer 502 or the photoresist mask 501 covers an ILD 504 not to be etched and does not cover an ILD 504 to be etched. In various embodiments, the ILD 504 can be substituted for various other dielectric or sacrificial materials (e.g., silicon-germanium).

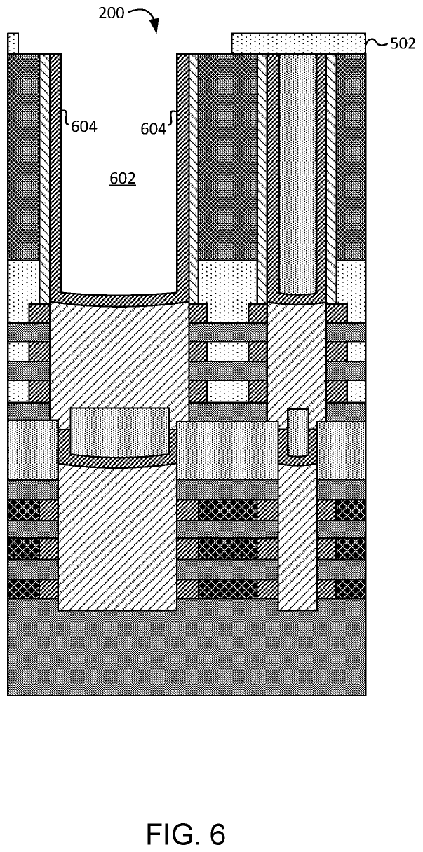

Corresponding to operation 108 of FIG. 1, FIG. 6 is a cross-sectional view of the semiconductor device 200 in which, an ILD 504 is etched to form an opening 602, in accordance with various embodiments.

As indicated above, the opening 602 can be formed by an etchant which is selective to the ILD 504 with regard to other portions of the semiconductor device 200. For example, the ILD 504 can be or include silicon dioxide and the etchant can be or include hydrofluoric acid. Other portions of the semiconductor device 200, such as the spacer 604 can be made from a material which is relatively resistant to the etchant. For example, the spacer 604 can be or include silicon nitride (SiN₄), or various silicides (e.g., cobalt silicides, titanium silicides, etc.). In various embodiments, the opening 602 can be formed from various materials, and the first etchant can include various materials, or can be formed by an anisotropic process based on the first patternable layer formed at operation 106. A lateral dimension of the opening 602 can be less than a lithographic limit. For example, the lateral dimension of the opening 602 can be less than about 20 nanometers, according to some embodiments. As depicted, the patternable layer 502 can be formed according to a lithographic process such that the opening therein can extend along a lateral dimension of the opening 602. Thus, the various contacts and openings described herein may be referred to as self-aligned contacts or self-aligned openings.

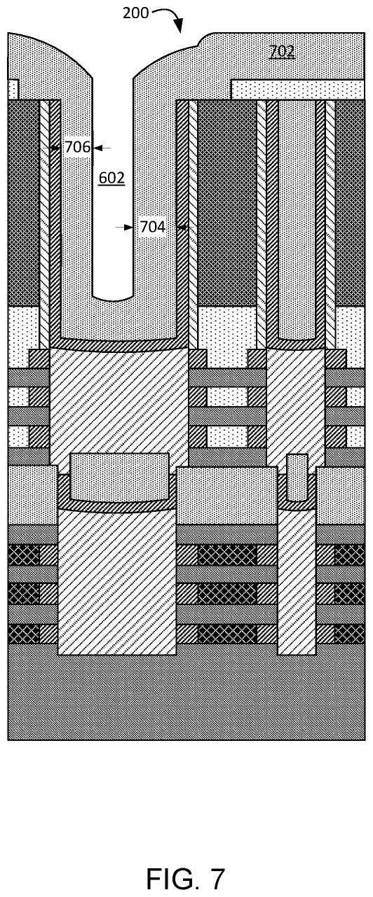

Corresponding to operation 110 of FIG. 1, FIG. 7 is a cross-sectional view of the semiconductor device 200 in which, a spacer layer 702 is deposited within the opening 602, in accordance with various embodiments.

A spacer layer 702 formed in the opening 602 can be formed by a thickness controlled process such as atomic layer deposition (ALD) process. Such a process can be isotropic or substantially anisotropic such that a dimension formed over vertical sidewalls is controlled. That is, the spacer layer 702 can be formed as a blanket layer. The process can include one or more cycles to control a thickness of the opening 602. For example, the ALD process can be repeated to a predefined dimension of the spacer layer 702 between the sidewall of the opening 602 formed at operation 108 and a remaining sidewall of the opening 602. The sidewalls of the opening 602 can form a dimension for a conductive element such as a contact for a first and second power signal (e.g., VDD and VSS) as is further described, such as with reference to operation 126 and 128. That is, a spacer thickness formed along opposing opening sidewalls 706, 704, can be equal such that a residual portion of the opening 602 is disposed at a center of the opening 602 formed according to operation 108. For example, the sidewall 704, 706 thicknesses can be less than 10 nanometers, such as about 5-8 nanometers. The centrality of the opening 602 can aid in centering a isolation layer, as discussed hereinafter with regard to operation 116.

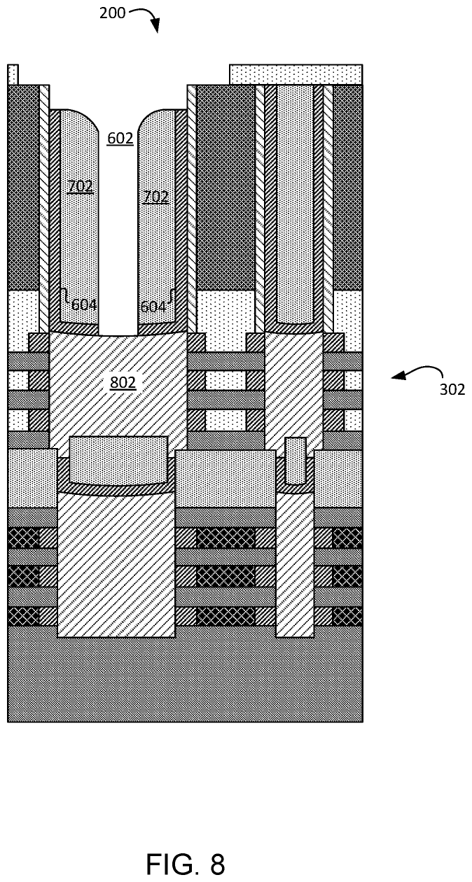

Corresponding to operation 112 of FIG. 1, FIG. 8 is a cross-sectional view of the semiconductor device 200 in which the spacer layer 702 formed at operation 110, is directionally etched to form a sidewall spacer 702 in the opening 602, in accordance with various embodiments.

The directional etch can remove a portion of the spacer 702 formed along the bottom of the opening 602 and over the top of the semiconductor device 200. As depicted, the upper portion of the sidewall of the opening 602 can include a cusped or reentrant corner. Thus, the opening 602 may extend vertically for a distance greater than in a completed semiconductor device 200 such that the cusped or reentrant corner can be planarized (e.g., at operation 128). The directional etch can further remove a portion of the spacer 604 defining the opening 602 at operation 108, which may be or include a same or different spacer material relative to the layer deposited at operation 110. That is, the directional etch can extend to a first source/drain region 802 associated with the first transistor 302 (e.g., an nEPI region, wherein the first transistor 302 is an n-type transistor). In some embodiments, the directional etch can include one or more operations (e.g., a first process to remove the layer deposited at operation 110, and a second process to remove the spacer 604 defining the opening 602 at operation 108). For example, one or more of the processes may be a directional process. The etchant can reveal an upper surface of an epitaxial layer (e.g., the nEPI region) of the first source/drain region 802.

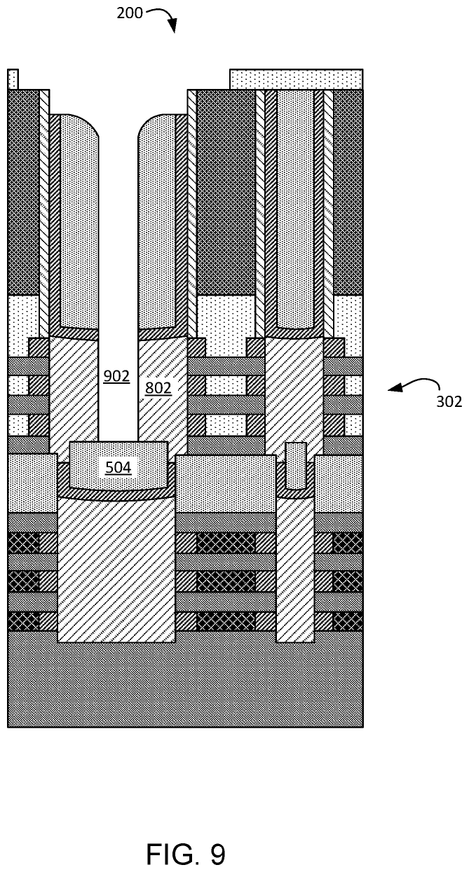

Corresponding to operation 114 of FIG. 1, FIG. 9 is a cross-sectional view of the semiconductor device 200 in which the opening 602 is directionally extended (e.g., etched) into an epitaxial layer of the semiconductor device 200 (e.g., associated with the n-type FET), to form a first recess 902 in accordance with various embodiments.

The first recess 902 can be formed by an anisotropic process, which may include a same or different etchant as operation 112. The extension can be a time/cycle based process or employ an etchant selective to the first source/drain region 802 of the first transistor 302 relative to the, for example, ILD 504 there below. In some embodiments, the etchant can extend the first recess 902 fully to or somewhat beyond the first source/drain region 802 into the ILD 504, such that a subsequent fill (at operation 116) can isolate the depicted first source/drain region 802 from the other portion of the epitaxial layer (depicted to the left of the first source/drain region 802, opposite from the first recess 902).

The epitaxial layer associated with the upper transistor (e.g., the first transistor 302, as depicted) of the semiconductor device 200 (e.g., the n-type FET) can extend between the bottom of the first recess 902 and an ILD material (e.g., silicon dioxide) disposed vertically between the transistors (e.g., between a p-type and n-type FET of a CFET pair). That is, the EPI region can be etched by an etchant which is selective to the epitaxial silicon relative to the ILD 504 (e.g., silicon dioxide ILD 504). For example, the etchant can include Ammonium Fluoride (NH4F), Tetramethylammonium Hydroxide (TMAH), or the like. At operation 114, or the various other operations described herein, a concentration, temperature, or time can be employed to achieve selectivity (e.g., an etching time to extend through the nEPI without extending through the ILD 504). In some embodiments, the first recess 902 may extend into at least a portion of the ILD 504. That is, a remaining vertical dimension of the ILD 504 can be greater than an isolation distance between the bottom of the first recess 902 and the pEPI layer associated with the p-type FET.

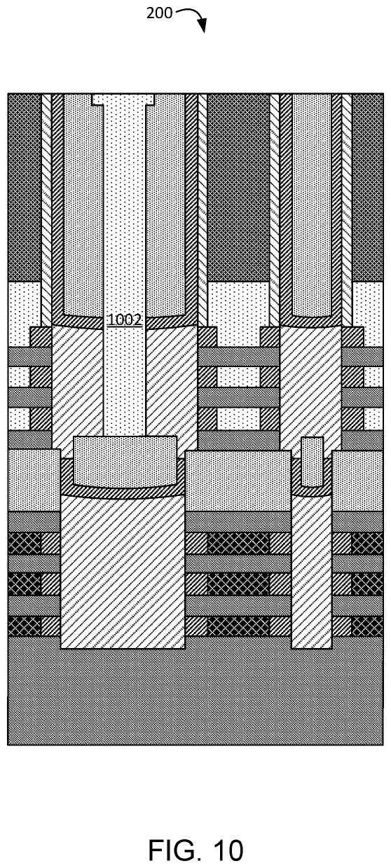

Corresponding to operation 116 of FIG. 1, FIG. 10 is a cross-sectional view of the semiconductor device 200 in which, an isolation layer 1002 is formed in the first recess 902, in accordance with various embodiments.

The isolation layer 1002 can be selected according to a dielectric constant (e.g., to reduce a parasitic capacitance). The isolation layer 1002 can also be selected such that silicon dioxide, or another material of the ILD 504 can be selectively etched away from the isolation layer 1002. For example, the isolation layer 1002 can comprise polyamide (PI), a spun on glass (SOG) such as boron phosphosilicate glass, or silicon nitride (Si₃N₄). In some embodiments, the isolation layer 1002 can include any number of sub-layers. For example, the isolation layer 1002 can include a dielectric layer (e.g., silicon dioxide) bounded by the spacer layer (not depicted) forming a boundary between the ILD 504 and the dielectric layer. For example, the spacer layer can include PI, a SOG or Si₃N₄. The isolation layer 1002 can fill the opening 602 to intermediate two laterally equal portions of the upper ILD 504 and the epitaxial layer (e.g., a silicon portion) of the first source/drain region 802.

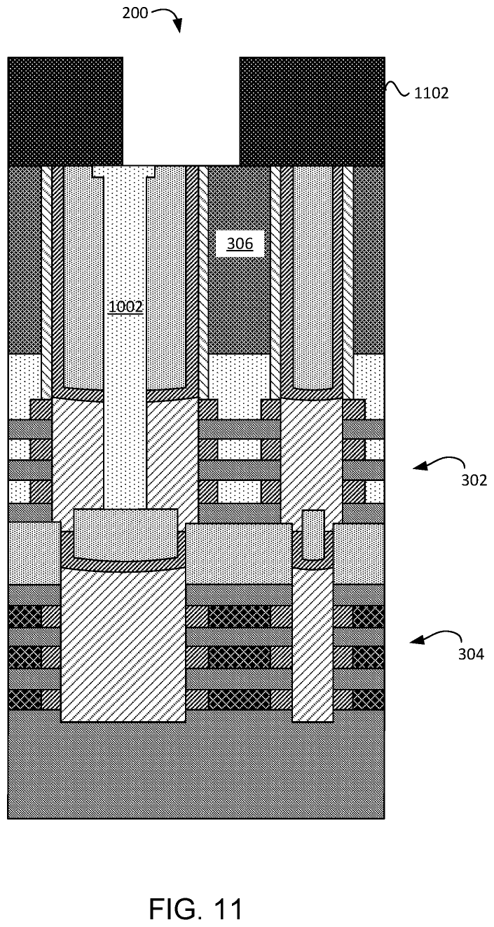

Corresponding to operation 118 of FIG. 1, FIG. 11 is a cross-sectional view of the semiconductor device 200 in which, a second patternable layer 1102 is formed, in accordance with various embodiments.

The second patternable layer 1102 can extend from the isolation layer 1002 to the gate structure 306 over the first transistor 302 and second transistor 304 (e.g., over a gate oxide therefor). Thus, the second patternable layer 1102 can mask a second recess extending from the isolation layer 1002 to a sidewall of the opening 602 as originally formed (e.g., to the spacer layer 604) from other portions of the ILD 504 along an upper surface of the semiconductor device 200. In various embodiments, the various patternable layers can vary, such as to etch the recesses disclosed herein in various sequences according to other elements of the device which are or are not selective thereto. The particular sequence and disposition of the patternable layers is not intended to be limiting. For example, in some embodiments, the second patternable layer 1102 can form the third recess and fourth recess, and a subsequent operation can form the second recess and may omit a mask layer or portion thereof.

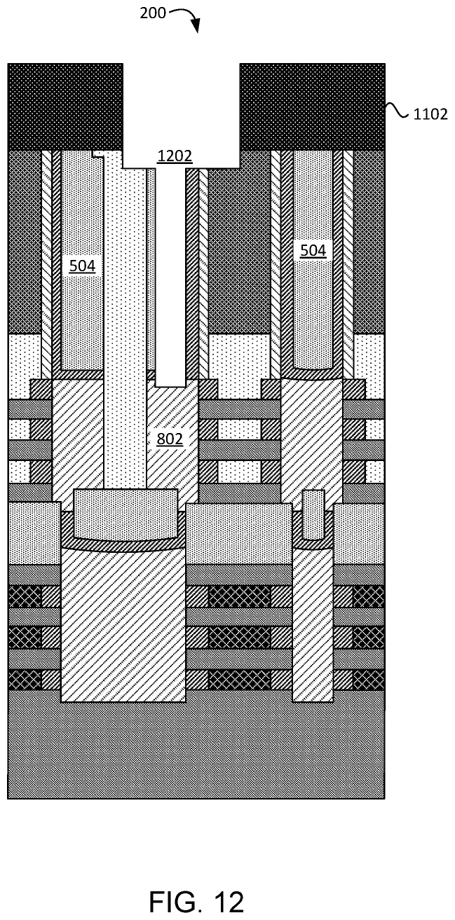

Corresponding to operation 120 of FIG. 1, FIG. 12 is a cross-sectional view of the semiconductor device 200 in which, a second recess 1202 is formed, in accordance with various embodiments. For example, the second recess 1202 can be formed according to the various suboperations discussed above, with regard to operation 108.

Although a portion of the ILD 504 or isolation layer (e.g., a spacer layer thereof) is shown as remaining, in some embodiments, the second recess 1202 can extend laterally between the isolation layer 1002 and the spacer layer 604 defining the opening 602 as depicted at operation 108. Further, although described as an “operation,” in some embodiments, the second recess 1202 may be formed in any number of operations or sub-operations. That is, operation 120, like the other operations disclosed herein can include various constituent operations. For example, a first portion of the second recess 1202 can be formed at a first operation comprising etching of the ILD 504, and a second portion of the second recess 1202 can be formed at a second operation comprising etching of the spacer defining a boundary between the ILD 504 and the first source/drain region 802 (e.g., nEPI layer).

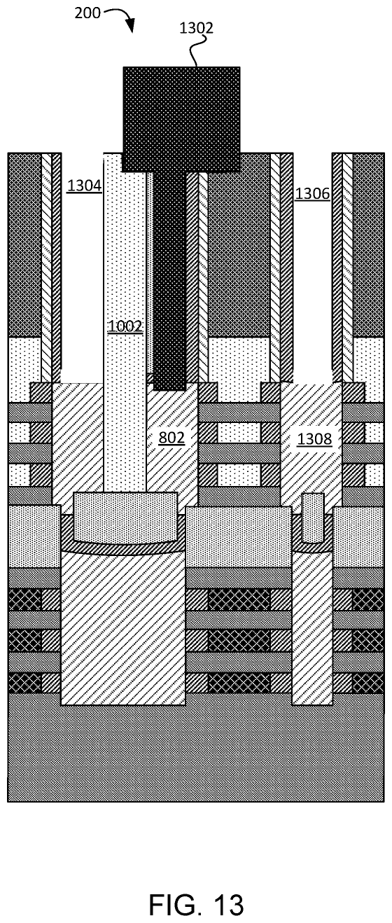

Corresponding to operations 122 and 124 of FIG. 1, FIG. 13 is a cross-sectional view of the semiconductor device 200 in which a third recess 1304 and a fourth recess 1306 are formed, in accordance with various embodiments.

The third recess 1304 and the fourth recess 1306 are defined according to a third patternable layer 1302 (or a mask associated therewith) defining a boundary between the second recess 1202 (depicted as filled) and each of the third recess 1304 and fourth recess 1306. The third patternable layer 1302 can cover or fill the second recess 1202 or cover a portion of the semiconductor device 200 (e.g., to the left and the right of the depicted portion of the semiconductor device 200). For example, the third patternable layer 1302 can be a regularly repeating pattern over a surface of the semiconductor device 200 to define a plurality of CFETs. Each of the second recess 1202 and the third recess 1304 can be defined according to the ILD 504 (e.g., may be self-aligned contacts based on the location of the ILD 504). As indicated above with regard to, for example, operations 108 or 112, the ILD 504 or other spacers can be etched according to one or more operations, etchants, cycles, or so forth. The third recess 1304 and fourth recess 1306 can extend through the ILD 504 to another portion of the semiconductor device 200. Particularly, the third recess 1304 can extend to a portion of the nEPI opposite from the isolation layer 1002 from the first source/drain region 802 of the first transistor 302. The fourth recess 1306 can extend to a portion of the nEPI opposite from the conductive channels of the first transistor 302. That is, the fourth recess 1306 can extend to a second source/drain region 1308 of the first semiconductor channel (corresponding to the first transistor 302).

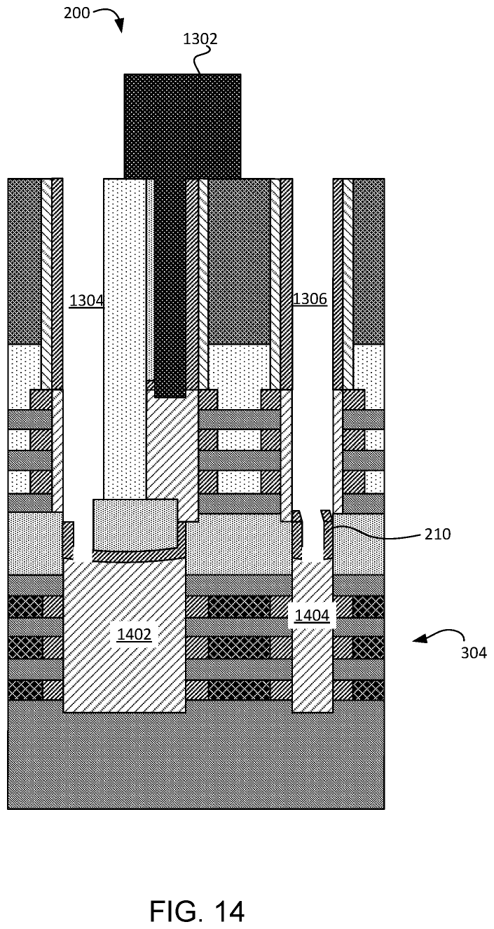

With continued correspondence to operation 124 of FIG. 1, FIG. 14 is a cross-sectional view of the semiconductor device 200 in which the third recess 1304 and fourth recess 1306 are extended, in accordance with various embodiments. Particularly, the recesses can extend through the nEPI of the n-type transistor, and any spacer layers 210 such that each of the third recess 1304 and fourth recess 1306 can extend to a pEPI layer. That is, the recesses may be extended according to the various sub-operations discussed above, such as with regard to operation 114. For example, an operation to punch through the spacer layer 210 can employ a same or different etchant relative to other portions of the semiconductor device 200. Particularly, the third recess 1304 can extend to a first source/drain region 1402 of the second semiconductor channel. The fourth recess 1306 can extend to a second source/drain region 1404 of the second semiconductor channel, the second semiconductor channel corresponding to the second transistor 304.

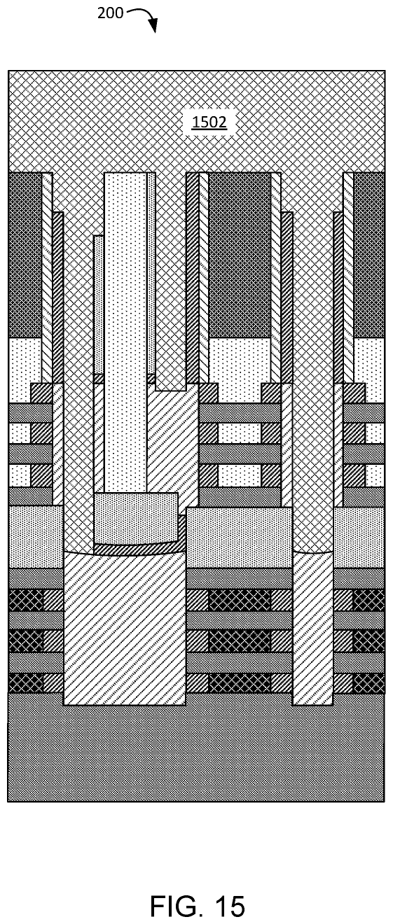

Corresponding to operation 126 of FIG. 1, FIG. 15 is a cross-sectional view of the semiconductor device 200 in which, a metal fill is deposited into the second recess 1202, the third recess 1304, and the fourth recess 1306, in accordance with various embodiments. The metal layer 1502 may be formed according to any suitable process, such as physical vapor deposition (PVD), chemical vapor deposition (CVD), electroplating, or so forth.

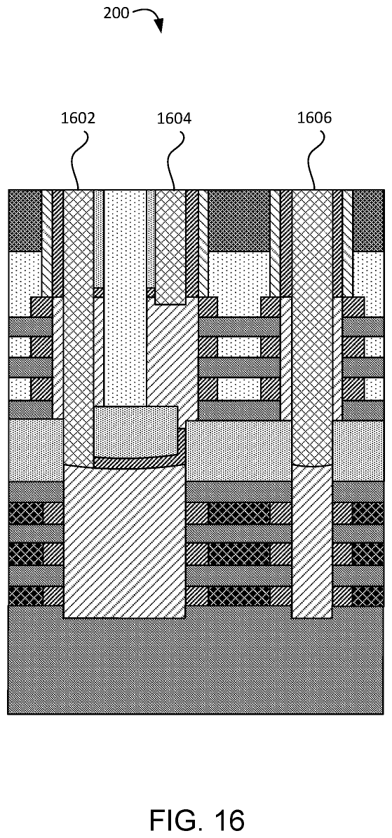

Corresponding to operation 128 of FIG. 1, FIG. 16 is a cross-sectional view of the semiconductor device 200 in which, the metal fill is electrically decoupled between the various recesses, in accordance with various embodiments. The metal fill of the metal layer (or other conductive layer) may be decoupled by planing an upper surface of the semiconductor device 200. For example, the semiconductor device 200 can be plarnarized according to a chemical-mechanical grinding/polishing CMG/P process to expose a top surface of the semiconductor device 200, having separate electrical contacts. Particularly, a first conductive element 1602, second conductive element 1604, and third conductive element 1606 are depicted. Moreover, the exposed surface of the gate structure 306 over the transistors is exposed which may be coupled to. For example, the gate structure 306 may be a metal gate structure 306 formed according to a gate-first process and coupled to, or a dummy gate structure 306 which is removed and replaced with a metal gate structure 306, according to a gate-last process.

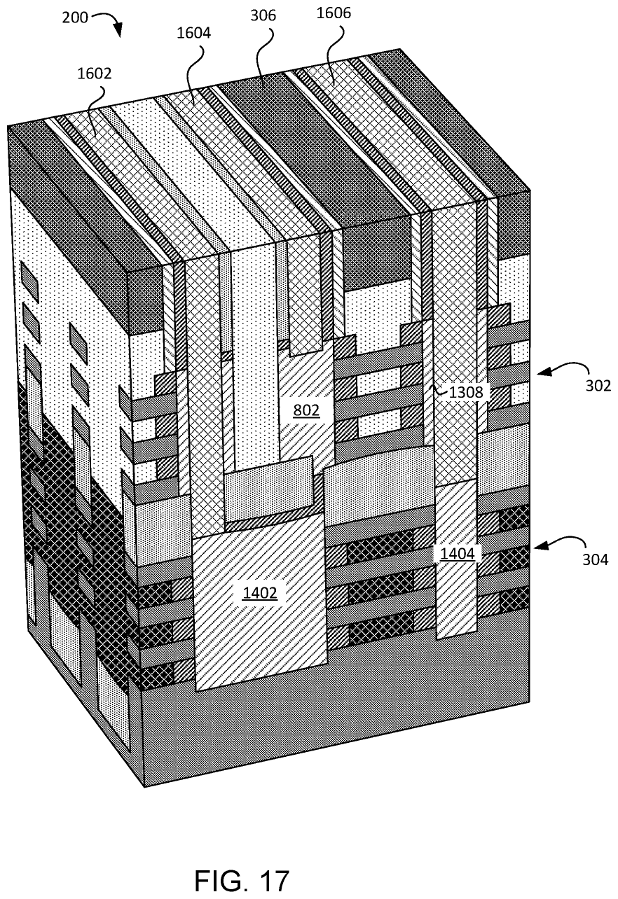

Referring now to FIG. 17, a profile view of a semiconductor device 200 is provided, in accordance with various embodiments. A first conductive element 1602 (e.g., a self-aligned trench) is depicted extending to (e.g., electrically coupled with) a first source/drain region 802 of the second semiconductor channel (e.g., corresponding to the first transistor 302). A second conductive element 1604 is depicted extending and electrically connected to the first source/drain region 1402 of the first semiconductor channel (e.g., a pEPI corresponding to the second transistor 304). A third conductive element 1606 is depicted extending and electrically connected to the second source/drain region 1308 of the first semiconductor channel (corresponding to the first transistor 302), as well as a second source/drain region 1404 of the second semiconductor channel (corresponding to the second transistor 304).

The first conductive element, the second conductive element, and the third conductive element can be interconnected to form an inverter, along with the metal gate structure 306. For example, the first conductive element 1602 can be a first power input (e.g., VSS). The second conductive element 1604 can be a second power input (e.g., VDD), the third conductive element 1606 can be an inverter output. The metal gate structure 306 can be an inverter input.

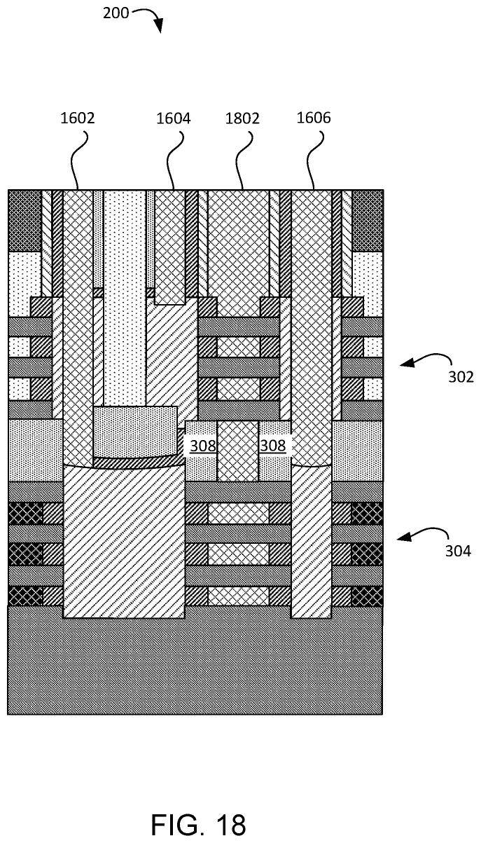

Referring now to FIG. 18, a depiction of a replacement of a dummy gate 306 with a metal gate structure 1802 is depicted, in accordance with some embodiments. The gate may be provided as a metal gate structure 1802 according to a gate-first process or, as previously described with regard to FIG. 16, the gate can be provided as a dummy gate 306 and thereafter replaced with a metal gate structure 1802. The dummy gate 306 can be removed by an etchant, which can remove each of a dummy gate 306 of the first transistor 302 and second transistor 304 (e.g., by an etchant selective to the dummy gates with respect to the semiconductor channel structures). In some embodiments, the metal gate structure 1802 can extend through a center of the dielectric portion 308. In some embodiments, an etchant used to remove the dummy gate structure is selective to the dielectric portion 308, wherein the metal gate structure 1802 for the first transistor 302 and second transistor 304 are electrically coupled away from the depicted face of the semiconductor device 200. That is, the dielectric portion 308 or a residual portion thereof can isolate the metal gate structure 1802 from the third conductive element 1606 the first source/drain region 802, or the third source/drain region 1402.

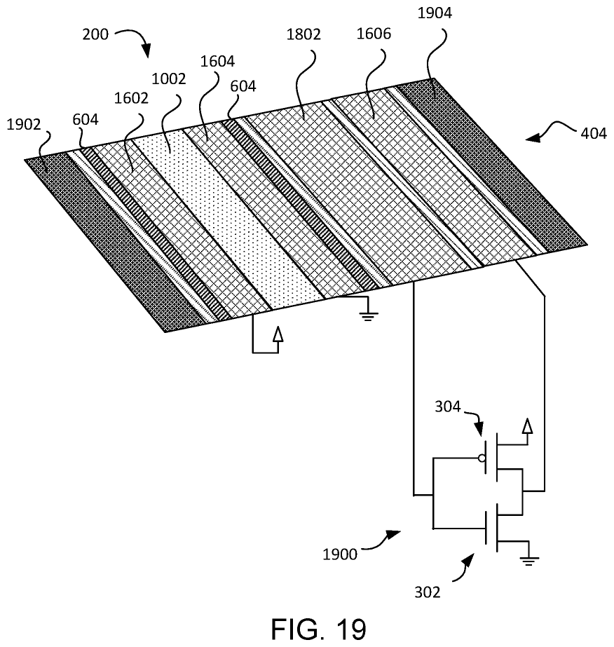

Referring now to FIG. 19, a hybrid view of a facing of a semiconductor device 200 and associated circuit diagram is provided, in accordance with some embodiments. Particularly, an upper face 404 of a semiconductor device 200 is provided, along with a schematic description of an inverter circuit 1900 including a first transistor 302 and second transistor 304, depicted as a n-type transistor and p-type transistor, respectively.

The depicted upper face 404 of the semiconductor device 200 includes the first conductive element 1602 and the second conductive element 1604, depicted as corresponding to VDD and VSS, respectively. As depicted, each of the first conductive element 1602 and the second conductive element 1604 can abut a spacer layer 604 at outward facing lateral extremes, and the isolation layer 1002 at inward facing lateral extremes. The metal gate structure 1802 can connect to the respective first and second semiconductor channels (e.g., can contact corresponding gate oxides, such as according to a GAA configuration). The second conductive element 1604 can contact a first source/drain region 802 of the first transistor 302. The third conductive element 1606 can contact a second source/drain region 1308 of the first transistor. The first conductive element 1602 can contact a third source/drain region 1402 of the second transistor 304 (which may also be referred to as a first drain/source region 1402 of the second transistor 304). Referring again to the third conductive element 1606, the conductive element can extend to the fourth source/drain region 1404 of the second transistor 304 (which may also be referred to as a second drain/source region 1404 of the second transistor 304). That is, according to the depicted embodiment, the second source/drain 1308 and fourth source/drain 1404 are sources, and the first source/drain 802 and third source/drain 1404 are drains. Various additional nanostructures of the device can be covered with various hardmasks or other dielectrics. For example, a first dummy gate structure 1902 and second dummy gate structure 1904 are disposed laterally exterior to an outward facing of the first conductive element 1602 and the third conductive element 1606.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments. Further, references to first, second, third, and the like are merely intended to discriminate between various depicted elements to aid in the description thereof. Such references do not define a position, sequence, or otherwise limit the various embodiments. For example, element “A” and element “B” can be referred to as first and second elements of a first embodiment, while similar elements may be referred to as second and first elements, or third and fourth elements of another embodiment, as may be useful to aid in their description such as to refer to various instances of gates, source/drains, conductive elements, and other components of a semiconductor device.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method for fabricating semiconductor devices, comprising:
providing a semiconductor device comprising a first semiconductor channel for a first transistor and a second semiconductor channel for a second transistor, vertically spaced from the first semiconductor channel;
etching a surface of the semiconductor device to define an opening bounded by a first sidewall and a second sidewall, opposite the first sidewall;
forming a blanket layer over the first sidewall and the second sidewall;
etching, directionally, a lower surface of the opening through a first source/drain structure of the first transistor to define a first recess;
filling the first recess with a first dielectric material;
removing a portion of the blanket layer between the first dielectric material and the second sidewall, to define a second recess;
removing a portion of the blanket layer between the first dielectric material and the first sidewall to define a third recess;
etching the surface of the semiconductor device to define a fourth recess over a second source/drain structure of the first transistor; and
extending, directionally, each of the third recess and the fourth recess, through the respective first and second source/drain structures of the first transistor, to a respective third and fourth source/drain structures of the second transistor.

2. The method of claim 1, comprising simultaneously forming the third recess and the fourth recess.

3. The method of claim 1, wherein the first semiconductor channel and the second semiconductor channel each comprise a plurality of nanostructures vertically spaced from each other.

4. The method of claim 1, wherein one of the first transistor or the second transistor is an n-type transistor and the other of the first transistor or the second transistor is a p-type transistor.

5. The method of claim 1, further comprising:
forming a conductive layer in the second, third, and fourth recess and over the semiconductor device; and
planarizing the surface of the conductive layer to electrically decouple the conductive layer between a first conductive element disposed in the third recess, a second conductive element disposed in the second recess, and a third conductive element disposed in the fourth recess.

6. The method of claim 1, wherein extending the fourth recess comprises etching a spacer layer disposed vertically between:
the second source/drain structure of the first transistor; and
the fourth source/drain structure of the second transistor.

7. The method of claim 1, wherein a lateral dimension of the second recess is equal to a lateral dimension of the third recess.

8. The method of claim 1, wherein forming the second recess comprises:
forming a patternable layer along the surface of the semiconductor device, the patternable layer comprising a minimum feature dimension which is greater than a lateral dimension of any of the second recess, the third recess, or the fourth recess.

9. The method of claim 1, wherein the third recess and the fourth recess are extended prior to a formation of the second recess.

10. The method of claim 1, wherein forming the blanket layer comprises a plurality of cycles of an atomic layer deposition (ALD) process.

11. The method of claim 1, further comprising:
forming a gate disposed laterally between the second recess and the fourth recess, wherein the gate electrically connects to a gate oxide contacting the first semiconductor channel and the second semiconductor channel.

12. The method of claim 11, wherein the gate surrounds the first semiconductor channel and the second semiconductor channel to form a gate-all-around (GAA) complementary field-effect transistor (FET).

13. A method for fabricating semiconductor devices, comprising:
providing:
a first transistor comprising a first semiconductor channel having a first end connected to a first source/drain and a second end connected to a second source/drain; and
a second transistor comprising a second semiconductor channel having a third end connected to a third source/drain and a fourth end connected to a fourth source/drain, wherein:
the second semiconductor channel is vertically spaced from and laterally aligned with the first semiconductor channel;
the first source/drain is vertically spaced from and laterally aligned with the third source/drain; and
the second source/drain is vertically spaced from and laterally aligned with the fourth source/drain;
exposing the first source/drain by etching through a first portion of the third source/drain;
filling the etched first portion with a dielectric material to form an isolation layer; and
forming a first conductive element to contact the first source/drain, a second conductive element to contact the third source/drain, and a third conductive element to contact the second and fourth source/drains, the isolation layer interposed between the first conductive element and the second conductive element.

14. The method of claim 13, wherein forming the first, second, and third conductive element comprises simultaneously:
filling of a first self-aligned contact opening;
filling of a second self-aligned contact opening; and
filling of a third self-aligned contact opening.

15. The method of claim 13, wherein the first transistor is an n-type transistor and the second transistor is a p-type transistor.

16. The method of claim 13, wherein the first transistor is a p-type transistor and the second transistor is an n-type transistor.

17. A semiconductor device comprising:
a first source/drain region of a first transistor laterally spaced from a second source/drain region of the first transistor, the first transistor vertically spaced from a second transistor;
a third source/drain region of the second transistor, the third source/drain region laterally spaced from a fourth source/drain region;
a first conductive element extending in a vertical direction to contact the first source/drain region;
a second conductive element extending in the vertical direction to contact the third source/drain region, the second conductive element extending a same lateral dimension as the first conductive element along an axis extending from the first conductive element to the second conductive element; and
a third conductive element extending in the vertical direction to contact the second source/drain region and the fourth source/drain region,
wherein the first conductive element extends vertically a lesser distance than either of the second conductive element or the third conductive element.

18. The semiconductor device of claim 17, wherein the first transistor is an n-type transistor, and the second transistor is a p-type transistor.

19. The semiconductor device of claim 17, wherein the first conductive element, the second conductive element, and the third conductive element are interconnected to form an inverter.

20. The semiconductor device of claim 17, wherein the first transistor comprises a plurality of nanostructures vertically spaced from each other.
